(19) United States
(12) Patent Application Publication
(10) Pub. No.: US 2005/0066109 A1
(43) Pub. Date: Mar. 24, 2005

(54) Method and apparatus for designing a computer system

(76) Inventors: Judson E. Veazey, Fort Collins, CO (US); Alexander Carlton, Cupertino, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/669,074

(22) Filed: Sep. 23, 2003

(51) Int. Cl. G11C 5/00

(52) U.S. Cl. 711/1

(57) ABSTRACT

In one embodiment, a method for designing a computer system comprises selecting an amount of internal memory for the computer system and providing the amount of internal memory to a non-linear exponential function to calculate a minimum input/output (I/O) transaction rate for transactions associated with a non-volatile memory subsystem appropriate for the amount of internal memory.

### BACKGROUND

Designing computing systems to perform under demanding criteria (e.g., systems that support numerous users, execute complex applications, are associated with limited responses times, etc.) can present a number of challenges. The design of such a computing system typically addresses the amount of internal memory that is appropriate and the amount of external memory associated with the input/output (I/O) subsystem. If the amount of internal memory is too small or if the I/O configuration is too small, system availability and response times may be seriously affected. Alternatively, if the amount of internal memory is too high or the I/O configuration is oversized, resources will be wasted upon the acquisition of unneeded equipment.

For example, FIG. 1 depicts a block diagram of system 100 that could be utilized to implement commercial, on-line transaction processing. To facilitate the concurrent processing of a relatively large number of transactions, system 100 includes server platform 101 to execute a relatively large number of applications 104. Applications 104 manage transactions to and from remote client systems 103 via the Internet 102. Applications 104 may identify available products and/or services, may receive orders from users, process payments for orders, schedule shipping of ordered items, and/or the like. To ensure that applications 104 are available and are able to perform these activities within acceptable response times, internal memory 105 and I/O subsystem 109 are provided. Internal memory 105 provides volatile random access memory (RAM) utilizing, for example, dual in-line memory modules (DIMMs). I/O subsystem 109 provides non-volatile memory utilizing suitable storage peripherals. I/O subsystem 109 includes a plurality of interface cards 106 to facilitate communication with a plurality of storage peripherals (e.g., disk drives 108) via buses 107.

The selection of the amount of internal memory 105 and the configuration of interface cards 106, buses 107, and drives 108 to ensure the proper execution of applications 104 has typically occurred using a trial-and-error approach. The trial-and-error approach is problematic because the amount of system administrator time required by the trial-and-error approach can be quite significant. Additionally, various “rules-of-thumb” may be utilized to facilitate the design process. For example, it may be assumed that one disk drive is required per 100 users. However, such rules-of-thumb cannot be easily applied as general techniques for a variety of platforms and applications.

### SUMMARY

In one embodiment, a method for designing a computer system comprises selecting an amount of internal memory for the computer system and providing the amount of internal memory to a non-linear exponential function to calculate a minimum input/output (I/O) transaction rate for transactions associated with a non-volatile memory subsystem appropriate for the amount of internal memory.

### BRIEF DESCRIPTION OF THE DRAWINGS

FIG. 1 depicts a system for executing applications utilizing internal memory and an I/O subsystem.

FIG. 2 depicts a graph that represents an optimal relationship between I/O transactions per second and an amount of internal memory available for a system according to one representative embodiment.

FIG. 3 depicts a flowchart for designing a computer system according to one representative embodiment.

FIG. 3A depicts a flowchart for designing a computer system according to another representative embodiment.

FIG. 4 depicts a system in which a design/administration software tool may be implemented according to some representative embodiments.

### DETAILED DESCRIPTION

Some representative embodiments of the invention utilize a mathematical model to determine the optimal relationship between the number of I/O transactions occurring as a function of time as issued by an application system and the memory size of the application system. One representative embodiment utilizes a non-linear, inverse exponential function to represent the relationship between the number of I/O transactions occurring as a function of time and the memory size of the application system. The parameters of the exponential function may be determined through non-linear regression based upon empirically determined values. After determining the parameters of the exponential function, the amount of memory in the application system is selected. The number of I/O transactions as a function of time that is appropriate for the selected amount of memory may be determined from the exponential function. From the number of I/O transactions, an I/O system may be configured to support the required number of I/O transactions.

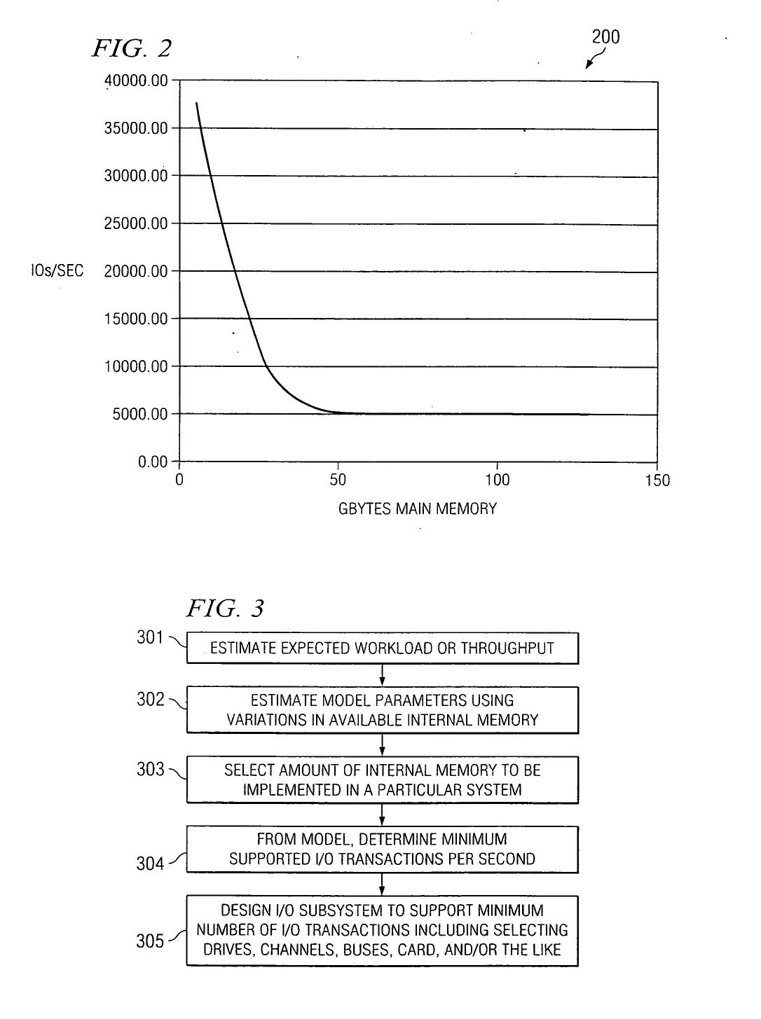

Some representative embodiments utilize a function of the form “io(m)=IOs/sec=a+e^{(c+bx)}” to model the relationship between the I/O configuration of a system and the amount of internal memory in the system for a fixed throughput. For the convenience of the reader, FIG. 2 depicts graph 200 according to this mathematical model that represents the relationship between the number I/O transactions per second associated with an I/O configuration and the appropriate amount of internal memory.

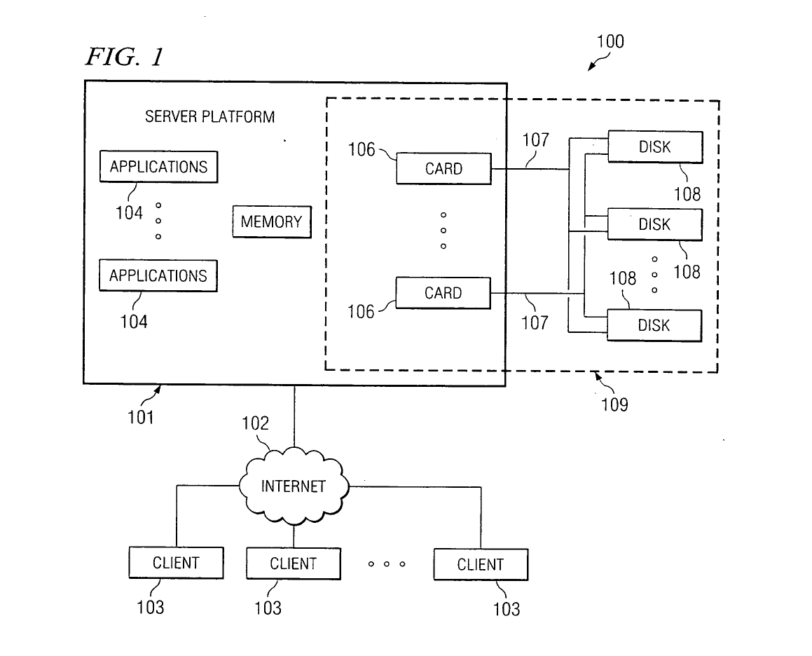

In this mathematical model, “io(m)” represents the number of I/O transactions that are performed per second by the I/O subsystem and “x” represents the amount of internal memory in the system for a fixed throughput or workload. The terms “a”, “b”, and “c” are parameters for the equation and may vary from platform to platform and from application to application. Parameter “a” defines the asymptotic limit for the number of I/O transactions as internal memory increases. The parameter “b” defines an exponential decay value from a maximum I/O transaction rate (as defined by both parameters “a” and “c”) to the asymptotic limit. The fixed throughput associated with the equation is determined by the workload associated with the system. Using system 100 of FIG. 1 as an example, the fixed throughput could be represented in reference to the number of applications 104 executing at any one time. Likewise, the fixed throughput could be represented in reference to the number of users and/or client systems 103 completing transactions using system 100.

The determination of the parameters “a,” “b,” and “c” may occur in a number of ways. In some representative embodiments, these parameters are determined utilizing statistical methods. Specifically, a given platform may be provided with a relatively substantial amount of internal memory. The platform may be operated with a given fixed workload or throughput and with a variable amount of available internal memory. The amount of available internal memory may be varied from the maximum amount of physically available memory using suitable operating system tools thereby avoiding the necessity of requiring physical removal of DIMMs or other memory components from the system. Upon operating the system under these conditions, the I/O rate may be measured for each variation in the amount of available internal memory. After several points are obtained, non-linear regression may be utilized to estimate the parameters “a,” “b,” and “c.”

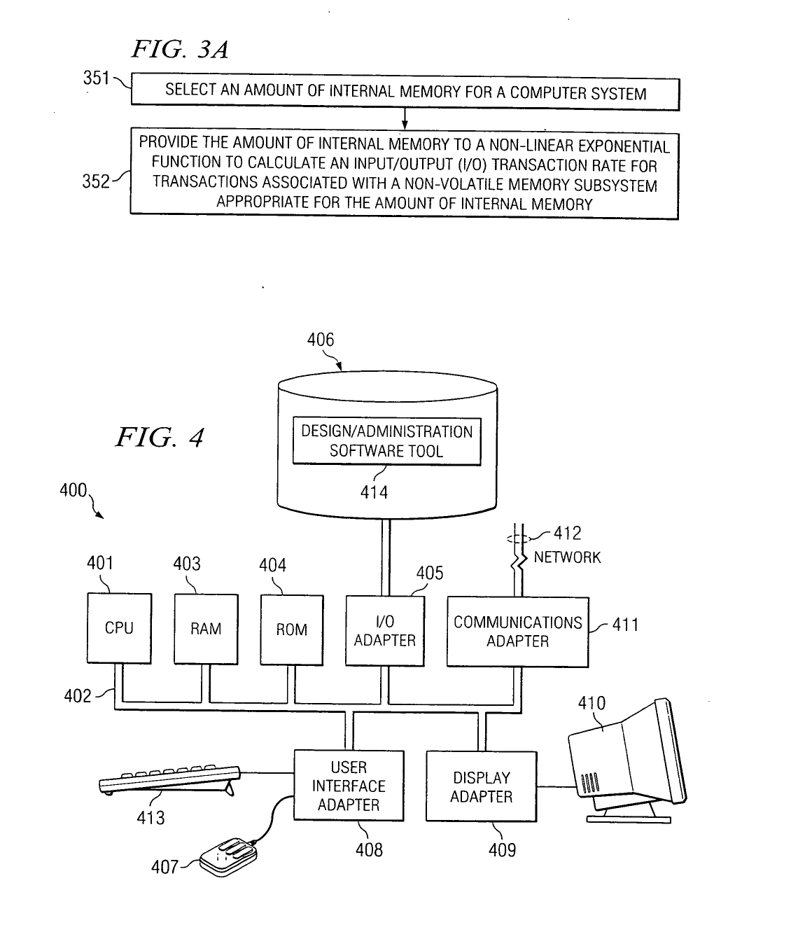

FIG. 3 depicts a flowchart for designing a computer system according to one representative embodiment. In step 301, an estimated workload or throughput is determined. In step 302, model parameters are estimated or determined utilizing, for example, variations in available internal memory as previously discussed. In step 303, an amount of internal memory for a particular system is selected according to, for example, the estimated workload or throughput determined in step 301. In step 304, from the model, the supported I/O transactions per second are determined. In step 305, the I/O subsystem is designed to support the number of I/O transactions. The design of the I/O subsystem may include selecting drives, channels, buses, cards, and/or the like.

The design of an I/O subsystem to support a specified amount of I/O transactions per second may occur utilizing known techniques. For example, the selection of various components and the number of components may occur utilizing several relatively straight-forward equations. The number of disks may be selected to equal the total rate of I/O transactions divided by the maximum I/O rate (as suggested by the manufacturer) of an individual disk for a selected disk type. The number of disks per channel may be selected to equal the channel bandwidth for a particular channel type divided by the expected workload. The total number of channels may be selected to equal the ceiling of (the lowest integer that is equal to or greater than) the total number of disks divided by the number of disks per channel. Subject to card limitations, the number of channels per card may be selected to equal the card bandwidth for a particular card type divided by the multiple of the workload and the number of disks per channel. Other I/O configuration issues may be addressed in a similar manner.

The calculation of the component requirements to facilitate selection of components for an I/O subsystem may occur in an automated manner utilizing a suitable software tool. For example, the limitations associated with the particular components (such as the maximum suggested I/O rate, the channel bandwidth, and/or the like) may be maintained in suitable tables. The tables may identify I/O limits based on the characterization of the maximum number of I/O transactions per second per disk, per channel, per card, per bus, and/or the like. When an I/O transaction rate to be supported is provided to the software tool, the software tool may retrieve suitable information from the tables to calculate the appropriate number of components and their configuration. Also, it shall be appreciated that different types of disks, cards, buses, and/or the like may be included within an I/O subsystem. Suitable variations to the design equations may be made to enable a user of the software tool to implement an I/O subsystem utilizing varied I/O subsystem components (e.g., different types of disks and/or the like).

Representative embodiments may be implemented in any number of ways. For example, a software capacity software tool may be implemented to enable consultants to plan the design and expansion of client systems. An I/O planning sub-module to a system administration toolkit may utilize the discussed mathematical model and associated calculations to manage I/O configuration by system administrators. Alternatively, representative embodiments may utilize general purpose software applications to implement I/O subsystem design selections. For example, a spreadsheet planning tool may be defined by a user according to the discussed mathematical model and associated calculations.

When implemented via executable instructions, various elements of such an embodiment of the present invention are in essence the code defining the operations of such various elements. The executable instructions or code may be obtained from a readable medium (e.g., hard drive media, optical media, EPROM, EEPROM, tape media, cartridge media, and/or the like) or communicated via a data signal from a communication medium (e.g., the Internet). In fact, readable media can include any medium that can store or transfer information.

FIG. 3A depicts a flowchart for designing a computer system according to another embodiment. The method comprises selecting an amount of internal memory for a computer system (step 351) and providing the amount of internal memory to a non-linear exponential function to calculate an input/output (I/O) transaction rate for transactions associated with a non-volatile memory subsystem appropriate for the amount of internal memory (step 352). The amount of internal memory may be selected by selecting a number DIMMs to be included with the computer system. The method may also include selecting a number of storage peripherals, selecting a number of buses for communication between the storage peripherals and the computer system, selecting a number of interface cards to communicate with the storage peripherals, and/or the like to support the I/O transaction rate. When selecting the number of storage peripherals, buses, interface cards, suitable performance limitation look-up transactions may be performed. The method may also be performed by a software application.

FIG. 4 illustrates computer system 400 adapted according to embodiments of the present invention. Central processing unit (CPU) 401 is coupled to system bus 402. CPU 401 may be any general purpose CPU. However, the representative embodiments are not restricted by the architecture of CPU 401 as long as CPU 401 supports the operations as described herein. Computer system 400 also includes random access memory (RAM) 403, which may be SRAM, DRAM, SDRAM, or the like. Computer system 400 includes ROM 404 which may be PROM, EPROM, EEPROM, or the like. RAM 403 and ROM 404 hold user and system data and programs as is well known in the art.

Computer system 400 also includes input/output (I/O) adapter 405, communications adapter 411, user interface adapter 408, and display adapter 409. I/O adapter 405 connects to storage devices 406, such as one or more of hard drive, CD drive, floppy disk drive, tape drive, to computer system 400. Storage devices 406 may store executable instructions according to certain representative embodiments. For example, as shown in FIG. 4, storage devices 406 store executable instructions for design/administration software tool 414. Software tool 414 may facilitate I/O subsystem configuration utilizing the discussed mathematical model and associated calculations, for example, by implementing steps 304 and 305 of FIG. 3.

Communications adapter 411 is adapted to couple computer system 400 to a network 412, which may be one or more of telephone network, local (LAN) and/or wide-area (WAN) network, Ethernet network, and/or Internet network. User interface adapter 408 couples user input devices, such as keyboard 413 and pointing device 407, to computer system 400. Display adapter 409 is driven by CPU 401 to control the display on display device 410.

By designing an I/O system configured in this manner, some representative embodiments provide a number of advantages. Specifically, some representative embodiments avoid iteratively varying the amount of internal memory selected for an application platform and the I/O configuration associated with the application platform. Thereby, system administrator time is not wasted. Moreover, the cost associated with the acquisition of the unneeded equipment is reduced or eliminated. Furthermore, response time and system availability issues are appreciably reduced or eliminated by identifying an amount of system resources appropriate for a given system throughput.

1. A method for designing a computer system, comprising:
selecting an amount of internal memory for said computer system; and
providing said amount of internal memory to a non-linear exponential function to calculate an input/output (I/O) transaction rate for transactions associated with a non-volatile memory subsystem appropriate for said amount of internal memory.

2. The method of claim 1 wherein said non-linear exponential function includes a parameter that defines an asymptotic limit for said I/O transaction rate.

3. The method of claim 2 wherein said non-linear exponential function defines a maximum I/O transaction rate.

4. The method of claim 3 wherein said non-linear exponential function includes a parameter that defines an exponential decay from said maximum transaction rate to said asymptotic limit as a function of an amount of internal memory.

5. The method of claim 4 wherein said non-linear function is of the form: a+e^{(c+bx)}, where x represents said amount of internal memory.

6. The method of claim 1 further comprising:
selecting a number of storage peripherals to support said I/O transaction rate.

7. The method of claim 6 further comprising:
selecting a number of buses for communication between said storage peripherals and said computer system to support said I/O transaction rate.

8. The method of claim 7 further comprising:
selecting a number of interface cards to communicate with said storage peripherals to support said I/O transaction rate.

9. The method of claim 8 further comprising:
looking up performance limitations associated with said storage peripherals, said buses, and said interface cards.

10. The method of claim 9 wherein said providing, said selecting a number of storage peripherals, selecting a number of interface cards, and said looking up performance limitations are performed by a software application.

11. The method of claim 1 wherein said selecting an amount of internal memory includes selecting a number of dual in-line memory modules (DIMMs) for said computer system.

12. A software application for designing a computer system, comprising:
code for receiving an amount of internal memory for said computer system; and
code for providing said amount of internal memory to a non-linear exponential function to calculate an input/output (I/O) transaction rate for transactions associated with a non-volatile memory subsystem appropriate for said amount of internal memory.

13. The software application of claim 12 wherein said non-linear exponential function includes a parameter that defines an asymptotic limit for said I/O transaction rate.

14. The software application of claim 13 wherein said non-linear exponential function defines a maximum I/O transaction rate.

15. The software application of claim 14 wherein said non-linear exponential function includes a parameter that defines an exponential decay from said maximum transaction rate to said asymptotic limit as a function of an amount of internal memory.

16. The software application of claim 15 wherein said non-linear function is of the form: a+e^{(c+bx)}, where x represents said amount of internal memory.

17. The software application of claim 12 further comprising:
code for selecting a number of storage peripherals to support said I/O transaction rate.

18. The software application of claim 17 further comprising:
code for selecting a number of buses for communication between said storage peripherals and said computer system to support said I/O transaction rate.

19. The software application of claim 18 further comprising:
code for selecting a number of interface cards to communicate with said storage peripherals to support said I/O transaction rate.

20. The software application of claim 19 further comprising:
code for looking up performance limitations associated with said storage peripherals, said buses, and said interface cards.

21. A system for designing a computer system, comprising:
means for receiving a selection of an amount of internal memory for said computer system; and
means for providing said amount of internal memory to a non-linear exponential function to calculate an input/output (I/O) transaction rate for transactions associated with a non-volatile memory subsystem appropriate for said amount of internal memory.

22. The system of claim 21 wherein said non-linear exponential function includes a parameter that defines an asymptotic limit for said I/O transaction rate.

23. The system of claim 22 wherein said non-linear exponential function defines a maximum I/O transaction rate.

24. The system of claim 23 wherein said non-linear exponential function includes a parameter that defines an exponential decay from said maximum transaction rate to said asymptotic limit as a function of an amount of internal memory.

25. The system of claim 24 wherein said non-linear function is of the form: a+e^{(c+bx)}, where x represents said amount of internal memory.
